(19) United States
(12) Patent Application Publication
(10) Pub. No.: US 2023/0292632 A1
(43) Pub. Date: Sep. 14, 2023

(54) Integrated Strain Relief in Nanoscale Dolan Bridges

(71) Applicant: National Technology & Engineering Solutions of Sandia, LLC, Albuquerque, NM (US)

(72) Inventors: Charles Thomas Harris, Albuquerque, NM (US); Sueli Del Carmen Skinner Ramos, Albuquerque, NM (US); William F. Kindel, Albuquerque, NM (US); Rupert M. Lewis, Albuquerque, NM (US); Matt Eichenfield, Albuquerque, NM (US)

(21) Appl. No.: 18/119,366

(22) Filed: Mar. 9, 2023

Related U.S. Application Data
(60) Provisional application No. 63/318,899, filed on Mar. 11, 2022.

(51) Int. Cl. H10N 60/12; G06N 10/40; H10N 69/00; H10N 60/01; H10N 60/80; H10N 60/85

(52) U.S. Cl. CPC H10N 60/12; G06N 10/40; H10N 69/00; H10N 60/0912; H10N 60/805; H10N 60/855

(57) ABSTRACT

Josephson junctions are the main circuit element of superconducting quantum information devices due to their nonlinear inductance properties and fabrication scalability. However, large scale integration necessarily depends on high fidelity and high yielding fabrication of Josephson junctions. The standard Josephson junction technique depends on a submicron suspended resist Dolan bridge that tends to be very fragile and fractures during the fabrication process. The present invention is directed to a new tunnel junction resist mask that incorporates stress-relief channels to reduce the intrinsic stress of the resist, thereby increasing the survivability of the Dolan bridge during device processing, resulting in higher Josephson junction yield.

### CROSS-REFERENCE TO RELATED APPLICATION

This application claims the benefit of U.S. Provisional Application No. 63/318,899, filed Mar. 11, 2022, which is incorporated herein by reference.

### STATEMENT OF GOVERNMENT INTEREST

This invention was made with Government support under Contract No. DE-NA0003525 awarded by the United States Department of Energy/National Nuclear Security Administration. The Government has certain rights in the invention.

### FIELD OF THE INVENTION

The present invention relates to quantum devices and, in particular, to a method of integrated strain relief in nanoscale Dolan bridges that can be used to fabricate tunnel junctions.

### BACKGROUND OF THE INVENTION

Superconducting Josephson junctions are the backbone of different devices in quantum information applications. See Z. K. Minev et al., Npj Quantum Inf. 7, 131 (2021); and J. Clarke and F. K. Wilhelm, Nature 453, 1031 (2008). The most notable property of Josephson junctions is the nonlinear inductance that these devices possess that is crucial for realizing superconducting quantum interference devices (SQUIDS) and superconducting qubits. See R. C. Jaklevic et al., Phys. Rev. Lett. 12, 159 (1964); Y. Mahklin and A. Shnirman, Nature 398, 305 (1999); and A. Osman et al., Appl. Phys. Lett. 118, 064002 (2021). In particular, a superconducting qubit's performance is intimately tied to the Josephson junction's critical current I_{c} because the critical current sets the Josephson coupling energy E_{J}=ℏI_{c}/(2e), where ℏ is the reduced Planck constant, and e the electron charge. See J. Clarke and F. K. Wilhelm, Nature 453, 1031 (2008); and M. H. Devoret et al., Phys. Rev. Lett. 64, 1824 (1990). Additionally, the junction capacitance C_{J} also plays a key role in understanding the qubit behavior because it provides information about the charging energy E_{c}=(2e)²/Cr. See J. Clarke and F. K. Wilhelm, Nature 453, 1031 (2008); and B. Jack et al., Phys. Rev. B 93, 020504 (2016). Because a Josephson junction's operating properties are highly dependent of the junction geometry and composition, fabrication remains the most important step in the development of superconducting qubits.

### SUMMARY OF THE INVENTION

The present invention is directed to a method of integrated strain relief in nanoscale Dolan bridges, comprising providing a bilayer resist stack, comprising a top resist layer on top of a bottom resist layer, on a substrate; patterning the bilayer resist stack with a Dolan bridge and one or more stress-relief channels lateral to the Dolan bridge; and developing the bilayer resist stack to provide a patterned mask comprising a suspended Dolan bridge and the one or more stress-relief channels in the top resist layer. The method can further comprise depositing a first metal layer by a first evaporation through the patterned mask at a first angle to the substrate; oxidizing an exposed top surface of the first metal layer to form a metal oxide layer on the first metal layer; depositing a second metal layer on portion of the metal oxide layer by a second evaporation at a second angle to the substrate, thereby forming a tunnel junction under the suspended Dolan bridge; and lifting-off the bilayer resist stack. The tunnel junction can comprise a Josephson junction. For example, the first metal can comprise aluminum and the metal oxide layer can comprise aluminum oxide.

As an example of the invention, Dolan bridges with 100 nm critical dimension were fabricated using a resist mask design that incorporated stress-relief channels with the standard self-aligned Josephson junction technique. The devices fabricated using an optimized mask design were found to have zero fractures or collapses which consequently resulted in higher fabrication yield of Josephson junctions. Using finite element method simulations, it was determined that the intrinsic stress in Dolan bridges made without stress-relief channels is greater than the mask material's (e.g., poly(methyl methacrylate), PMMA) tensile strength, and therefore the main contributor of fracture and collapse. From calculations, the PMMA's intrinsic stress can be reduced by a factor of three, to values below the PMMA tensile strength, if stress-relief channels are incorporated in the mask design. The fabricated Josephson junctions were characterized at room temperature using the Ambegaokar-Baratoff relationship. From this characterization, a junction area of 100 nm×200 nm with a tunnel barrier oxidized at 500 mTorr was chosen to be part of a transmon qubit that was characterized by dispersively coupling to a readout resonator from which T₁=1.52 μs and T₂*=114 ns were calculated.

### BRIEF DESCRIPTION OF THE DRAWINGS

The detailed description will refer to the following drawings, wherein like elements are referred to by like numbers.

FIGS. 1A-1D are schematic illustrations of the fabrication process of a Josephson junction (not to scale).

FIG. 2A is an SEM image of the resist mask of a self-aligned Josephson junction with a collapsed Dolan bridge, and (inset) the design parameters w₁, w₂ and g. FIG. 2B is an SEM image of the resist mask after adding lateral stress relief channels. FIG. 2C is an SEM image of integrated stress-relief channels to avoid possible parasitic capacitance. FIGS. 2D and 2E are corresponding SEM images after metal liftoff. All scale bars are 1 μm.

FIG. 3A is a simulation of the stress in the Dolan bridge after the resist stack has been developed without the stress-relief channels. FIG. 3B is a simulation with the stress-relief channels. FIG. 3C is a graph of calculated lateral stress-tensor components from the FEM simulation of the Dolan bridge domain with (squares) and without (dots) the stress channels.

FIG. 4 is a graph of normal resistances values of the Josephson junctions with different areas at varied oxidation pressures. The areas fabricated for the Josephson junctions were 100 nm×100 nm, 100 nm×200 nm, 100 nm×300 nm, 100 nm×400 nm, and 100 nm×500 nm. The oxidation pressures used to define the tunnel barrier were 1 Torr, 500 mTorr and 250 mTorr.

FIG. 5A is an optical image of the readout circuit and transmon qubit device after the fabrication process. The resonator is a λ/2 co-planar waveguide resonator that couples with the qubit. FIG. 5B is an optical image of the entire transmon qubit that consist of an interdigitated capacitor and 20 μm SQUID loop. FIG. 5C is an SEM image taken of the SQUID loop. FIG. 5D is an SEM image of a Josephson junction with an area of 100 nm×200 nm.

FIG. 6A is a graph of the amplitude of the qubit readout tone as the duration and frequency of a preceding tone on the qubit is adjusted. FIG. 6B is a plot of the qubit lifetime. FIG. 6C is a graph of the Ramsey sequence of the qubit. FIG. 6D is a graph of the qubit's coherence time.

### DETAILED DESCRIPTION OF THE INVENTION

The present invention is directed to a fabrication process that implements a new Dolan bridge mask design that has been used to successfully pattern critical features of 100 nm dimensions in the resist stack. The process can be used to fabricate tunnel junctions. This was accomplished by adding stress-relief channels to diminish intrinsic stresses that otherwise cause resist fractures in the tunnel junction mask layer. The process consists of a single development step which makes fabrication substantially faster than other techniques, like cold development and orthogonal resist, which also aim to resolve the undercut conundrum. See J. M. Kreikebaum et al., Supercond. Sci. Technol. 33, 06LT02 (2020); K. Koshelev et al., J. Vac. Sci. Technol. B 29, 06F306 (2011); L. Ocola and A. Stein, J. Vac. Sci. Technol. B 24, 3061 (2006); W. W. Hu et al., J. Vac. Sci. Technol. B 22, 1711 (2004); B. Cord et al., J. Vac. Sci. Technol. B 24, 3139 (2006); and S. M. Tanner and C. T. Rogers, J. Vac. Sci. Technol. B 26, 481 (2008). As an example of the invention, experimental results and stress analysis of the lithography resist stack demonstrate the performance of a Josephson junction mask layer with and without the stress relief channels.

### Fabrication Method

Exemplary Josephson junctions were fabricated using the standard Al/AlOₓ/Al material stack, implemented in previous works. See J. M. Kreikebaum et al., Supercond. Sci. Technol. 33, 06LT02 (2020); G. J. Dolan, Appl. Phys. Lett. 31, 337 (1977); I. M. Pop et al., J. Vac. Sci. Technol. B 30, 010607 (2012); and A. Potts et al., IEE Proc. Sci. Meas. Technol. 148, 225 (2001), which are incorporated herein by reference. Because the junction oxide is very thin and the thickness must be accurately controlled, an in-situ self-aligned technique is used wherein the reactive aluminum from a first evaporation is exposed to oxygen at a fixed concentration and pressure for a given time, and then a second aluminum evaporation is performed without breaking vacuum in the deposition chamber. However, since only one lithographic step can be performed using this technique, the second evaporation is performed at an angle to the first evaporation in order to form the junction.

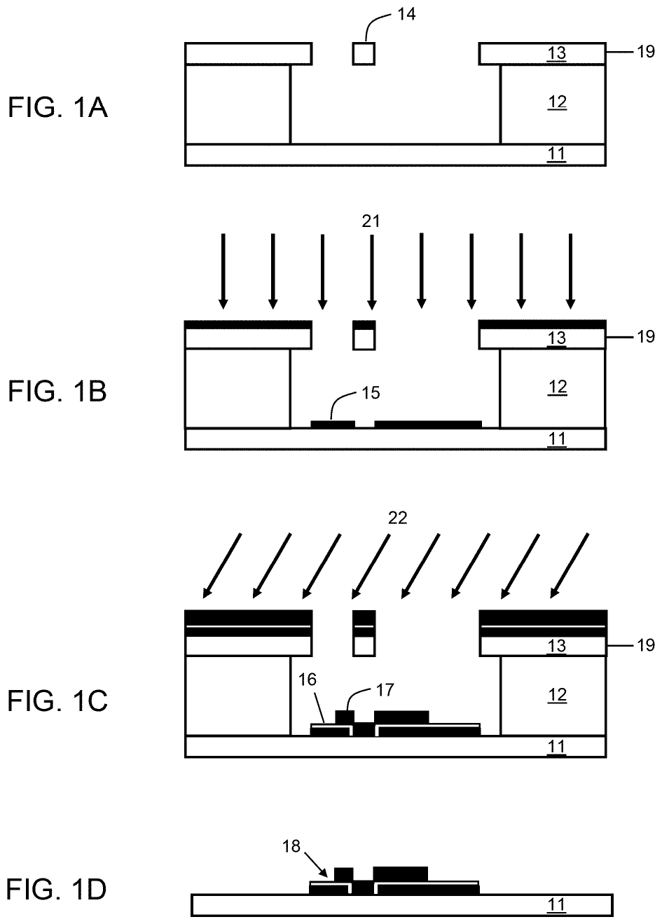

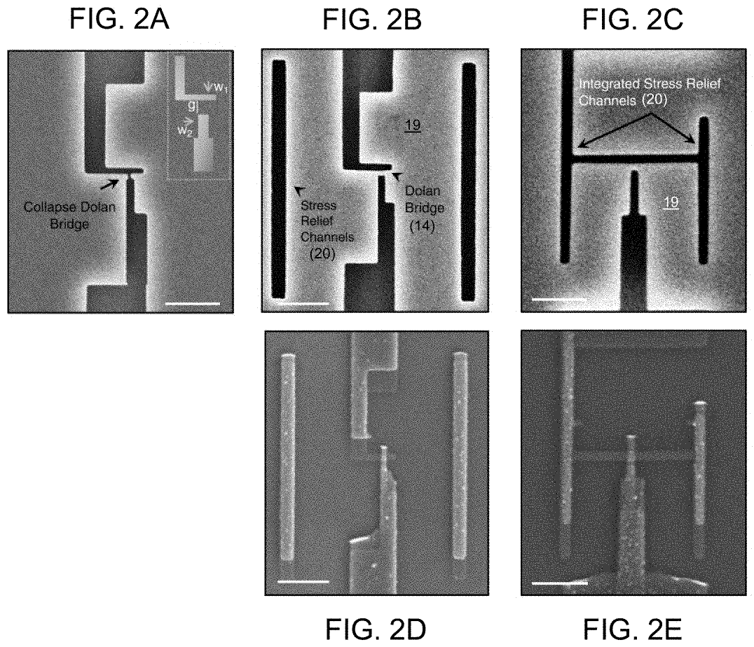

As shown in FIG. 1A, an exemplary fabrication process starts by spin coating a bilayer resist stack, consisting of a 760 nm thick methyl methacrylate (MMA) layer 12 under a 180 nm thick poly(methyl methacrylate) PMMA layer 13, on a silicon substrate 11. Although other resist materials can be used, the use of MMA-based polymers for both of the layers enables development with a single developer at room temperature. The top resist layer 13 is then patterned using e-beam lithography and developed in a MIBK:IPA solution which selectively undercuts the MMA thereby leaving a suspended PMMA bridge, known as a Dolan bridge 14. See G. J. Dolan, Appl. Phys. Lett. 31, 337 (1977). Stress-relief channels 20 lateral to the Dolan bridge 14 can also be patterned in the mask 19, as shown in FIG. 2B. As shown in FIG. 1B, a 20 nm thick layer of aluminum 15 is then deposited normal to the substrate surface using e-beam shadow first evaporation 21 with a base pressure of 2×10⁻⁷ Torr. Immediately after the evaporation, O₂ is flowed into the chamber for 10 minutes to oxidize the Al, thereby forming a thin layer of aluminum oxide 16 which will serve as the Josephson junction tunnel barrier. For example, the aluminum oxide thickness can be approximately 10 Angstroms. Different oxidation pressures were explored to modify the tunnel barrier thickness and therefore the Josephson junction critical current. As shown in FIG. 1C, a 40 nm thick Al layer 17 is then deposited with a second evaporation 22 with the sample rotated at a 30 degree angle from normal. The resist layers are then removed by metal liftoff, as shown in FIG. 1D. This double angle evaporation technique will produce identical metal features that are laterally offset such that their overlap under the shadow of the Dolan bridge creates the Josephson junction 18.

It is worth noting that the patterned resist bridges, used in the standard self-aligned junction technique, tend to collapse after development as seen in the scanning electron microscope (SEM) image in FIG. 2A. Emerging mechanical stresses during fabrication are thought to be the cause of the collapsing Dolan bridges. As such, instead of using other more time-consuming fabrication processes, stress-relief channels 20 can be incorporated into the resist mask 19 (see FIGS. 2B-2C) to maintain the dialed-in fabrication flow thereby minimizing processing time and difficulty. The critical geometric parameters affecting the Dolan bridge survivability and Josephson junction performance are the width of the horizontal finger w₁, the width of the vertical finger w₂, and the gap between them g, as shown in the inset in FIG. 2A. For the exemplary devices, w₁ and g were kept constant at 100 nm, while w₂ was varied from 100 nm to 500 nm in increments of 100 nm. FIGS. 2D-2E show the SEM images taken of the resulting stress-relieved devices after metal lift-off, where the “shadow image” from the double angle evaporation technique is clearly visible.

### Dolan Bridge Stress Simulation

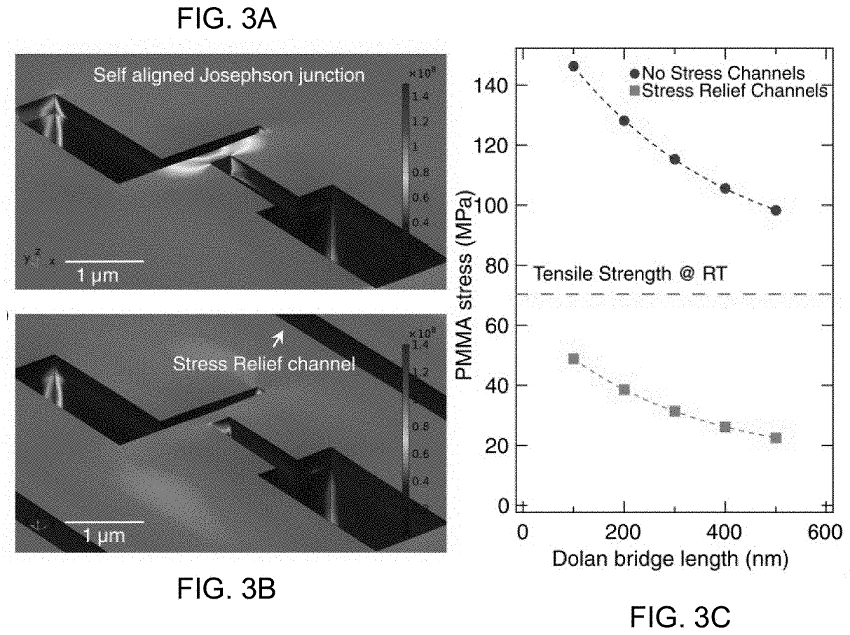

Finite element method (FEM) simulations of the bilayer resist mask and substrate were performed using COMSOL Multiphysics to confirm that excessive mechanical stresses are the cause of Dolan bridge fracture. The intrinsic stresses in the Dolan bridge domain of two designs, a standard self-aligned Josephson junction without (FIG. 3A) and with (FIG. 3B) stress-relief channels, were compared. The simulation consisted of a parameter sweep where the width of w₂ was varied from 100 nm to 500 nm, and the intrinsic lateral stress-tensor components were calculated. The simulation results reveal, as shown in FIG. 3C, that incorporating stress-relief channels reduces the intrinsic stress in the Dolan bridge domain by a factor of three, thereby bringing the intrinsic stress below the tensile strength of PMMA, ˜70 MPa. See L. Wei et al., Mater. Sci. Eng. A 492, 102 (2008); R. Jeffrey et al., “A 2d experimental method with results for hydraulic fractures crossing discontinuities,” ARMA-2015-439 (2015); and A.-W. Adel et al., Polym. Test. 58, 86 (2017). The Dolan bridges in standard (no stress-relief channels) self-aligned Josephson junction designs collapse because the intrinsic stress in the resist-stack generally surpasses the tensile strength of PMMA. It is worth noting that, to date, masks that have been patterned and developed with the stress-relief channel design have resulted in zero Dolan bridge breaks.

### Josephson Junction Normal Resistance

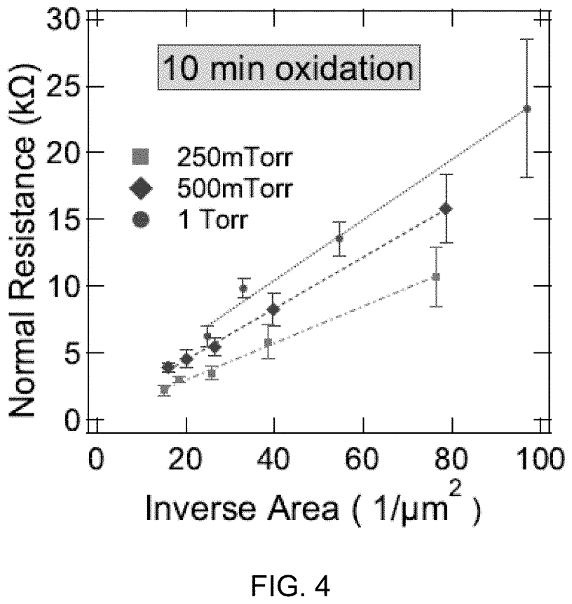

The Josephson junction devices fabricated with stress-relief channels were electrically characterized at room temperature, where a normal resistance was measured for the different junction areas fabricated at the varied oxidation pressures. The junction's critical current I_{c} can be calculated from the normal resistance values using the Ambegaokar-Baratoff equation (1):

$${I}_{c} {R}_{n} = \frac{π Δ}{2 e} \qquad ( 1 )$$

where Δ is the superconducting gap, 182 meV for aluminum, and Rₙ is the room temperature resistance (also known as normal resistance). See V. Ambegaokar and A. Baratoff, Phys. Rev. Lett. 10, 486 (1963). The results, plotted in FIG. 4, are from different double angle evaporation runs, where at least 20 junctions were measured for each area at every oxidation fabrication pressure. The oxidation pressures were 250 mTorr, 500 mTorr and 1 Torr, which resulted in junctions with corresponding critical current ranging from 26 nA to 130 nA, 18 nA to 73 nA, and 12 nA to 45 nA, respectively. These results provide valuable information for designing qubits since the critical current will set the qubit's Josephson energy.

### Transmon Qubit

To demonstrate the quality of the optimized mask design, Josephson junctions were fabricated as part of a transmon-style superconducting qubit and its performance was characterized. See J. Koch et al., Phys. Rev. A 76, 042319 (2007). The qubit was fabricated on a high-resistivity silicon substrate using double angle Al evaporation forming an Al/AlOₓ/Al junction, and 100 nm×200 nm Josephson junctions were defined with the stress-relief channels using e-beam lithography.

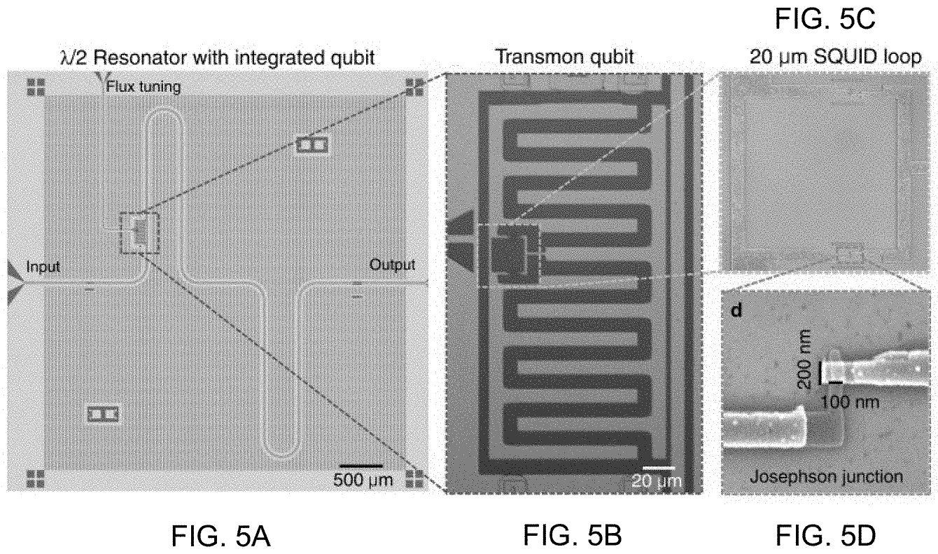

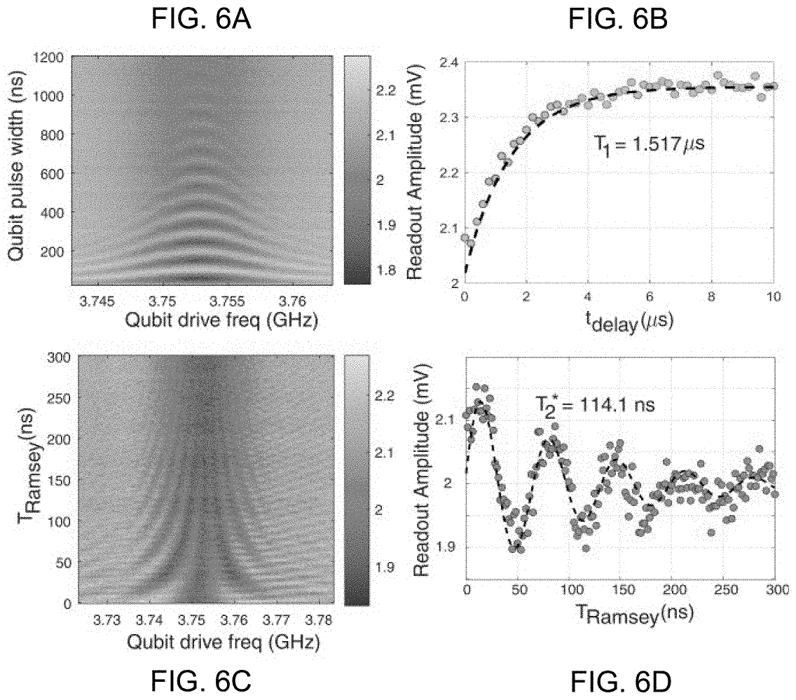

The readout resonator and control circuitry, shown in FIG. 5A along with the transmon qubit, consists of a 100 nm thick layer of Al that was deposited on to a photolithographically defined resist mask. The transmon qubit (FIG. 5B) consists of two Josephson junctions (FIG. 5D) forming a SQUID loop (FIG. 5C) shunted by an integrated capacitor. The qubit is parametrized by the effective Josephson energy E_{J} of its SQUID loop and the charging energy E_{c} of its total capacitance. From spectroscopy, the qubit has E_{c}/h=261 MHz (74.2 fF of effective capacitance), E_{J}/h=11.7 GHz (I_{c}=11:8 nA per junction), and maximum frequency f_{q}=4.682 GHz. The qubit's effective Josephson energy of its SQUID loop can be tuned down by threading flux through the SQUID loop via the flux tuning line. To facilitate reading out the state of the qubit, it was dispersively coupled to a readout resonator with resonate frequency fᵣ=5.511 GHz, linewidth κ/2π=5.5 MHz by nominal coupling rate g/h=79 MHz. Qubit characterization was accomplished by tuning the qubit down to roughly f_{q}=3.75 GHz in order to avoid deleterious two-level systems near the qubit's maximum frequency. The qubit was dispersively readout by driving a 1 μs pulsed tone through the readout resonator, which is on resonance when the qubit is in its ground state. Thus, high values of the readout amplitude were measured when the qubit was in the ground state and low values when the qubit was in the excited state. The π- and π/2-pulses were calibrated on the qubit for characterization by adjusting the duration and frequency of a pulsed qubit drive as shown in FIG. 6A. The qubit's lifetime T₁ was calculated by exciting the qubit with a π-pulse and adjust a delay time t_{delay} before reading out the qubit (FIG. 6B). From this measurement, a T₁=1.52 μs was inferred. The qubit's coherence time T₂* was obtained by performing a Ramsey sequence of two π/2-pulses with a t_{Ramsey} delay between the two pulses followed by qubit readout, and repeating this measurement while adjusting t_{Ramsey} and the frequency of the π/2-pulse drive (FIGS. 6C-D). From this measurement, a T₂*=114 ns was inferred.

The present invention has been described as a method of integrated strain relief in nanoscale Dolan bridges that can be used to fabricate tunnel junctions. It will be understood that the above description is merely illustrative of the applications of the principles of the present invention, the scope of which is to be determined by the claims viewed in light of the specification. Other variants and modifications of the invention will be apparent to those of skill in the art.

We claim:

1. A method of integrated strain relief in nanoscale Dolan bridges, comprising:
providing a bilayer resist stack, comprising a top resist layer on top of a bottom resist layer, on a substrate;
patterning the bilayer resist stack with a Dolan bridge and one or more stress-relief channels lateral to the Dolan bridge; and
developing the bilayer resist stack to provide a patterned mask comprising a suspended Dolan bridge and the one or more stress-relief channels in the top resist layer.

2. The method of claim 1, further comprising:
depositing a first metal layer by a first evaporation through the patterned mask at a first angle to the substrate;
oxidizing an exposed top surface of the first metal layer to form a metal oxide layer on the first metal layer;
depositing a second metal layer on portion of the metal oxide layer by a second evaporation at a second angle to the substrate, thereby forming a tunnel junction under the suspended Dolan bridge; and
lifting off the bilayer resist stack.

3. The method of claim 2, wherein the tunnel junction comprises a Josephson junction.

4. The method of claim 2, wherein the first metal comprises aluminum.

5. The method of claim 2, wherein the metal oxide layer comprises aluminum oxide.

6. The method of claim 2, wherein the first angle is normal to the substrate.

7. The method of claim 1, wherein the bilayer resist stack comprises (methyl methacrylate)-based polymers.
